(19) United States
(12) Patent Application Publication
(10) Pub. No.: US 2024/0331753 A1
(43) Pub. Date: Oct. 3, 2024

(54) Magnetic Memory Cell and Magnetic Memory

(71) Applicant: ZHEJIANG HIKSTOR TECHNOLOGY CO., LTD., Hangzhou, Zhejiang (CN)

(72) Inventors: Junlu GONG, Hangzhou, Zhejiang (CN); Hong JIAN, Hangzhou, Zhejiang (CN); Yihui SUN, Hangzhou, Zhejiang (CN); Fantao MENG, Hangzhou, Zhejiang (CN)

(21) Appl. No.: 18/575,281

(22) PCT Filed: Mar. 3, 2022
(86) PCT No.: PCT/CN2022/078967

§ 371 Date: Dec. 28, 2023

(30) Foreign Application Priority Data
Mar. 5, 2021 (CN) 202110245652.1

(51) Int. Cl. G11C 11/16; H01F 10/32; H10B 61/00; H10N 50/10; H10N 50/80

(52) U.S. Cl. CPC G11C 11/161; H01F 10/3272; H10B 61/00; H10N 50/10; H10N 50/80

(57) ABSTRACT

Disclosed are a magnetic memory cell and a magnetic memory. The magnetic memory cell sequentially includes a first electrode, a transition combination layer, a Magnetic Tunnel Junction (MTJ), and a second electrode from bottom to top. The first electrode and the second electrode are used to connect to an external circuit, and used to control a resistance state of the MTJ. The transition combination layer includes at least one boron supply layer and at least one boron adsorption buffer layer that are stacked.

### CROSS-REFERENCE TO RELATED APPLICATIONS

The application claims priority to Chinese Patent Application No. 202110245652.1, filed to the China National Intellectual Property Administration on Mar. 5, 2021 and entitled “Magnetic memory cell and Magnetic Memory”, the disclosure of which is hereby incorporated by reference in its entirety.

### TECHNICAL FIELD

The disclosure relates to the field of magnetic storage, and in particular to a magnetic memory cell and a magnetic memory.

### BACKGROUND

A Magnetic Random Access Memory (MRAM) is composed of a Magnetic Tunnel Junction (MTJ) array, and a core structure of the MTJ includes a free layer, a barrier layer, and a fixed layer. The free layer and the fixed layer are magnetic layers, and the barrier layer is a very thin insulating layer with a thickness generally less than 2 nm. When the MTJ works normally, a magnetization direction of the fixed layer is unchanged, a magnetization direction of the free layer may be changed by an external magnetic field or an input current, and a resistance value of the MTJ is determined by the relative magnetization directions of the free layer and the fixed layer. When the magnetization direction of the free layer is parallel to that of the fixed layer, the MTJ is in a low resistance state. When the magnetization direction of the free layer is anti-parallel to that of the fixed layer, the MTJ is in a high resistance state. The resistance state of the MTJ is controlled by the relative states of the magnetization directions of the free layer and the fixed layer, which is one of the physical principles of the operation of an MTJ device.

For an MTJ thin film stack, the thin film structure and interface characteristics have a very important effect on the performance. However, in the manufacturing process of a magnetic memory cell in the related art, due to the fact that various processes need to be performed in a high temperature environment, a phenomenon of the interface diffusion between films is inevitably generated, which leads to the degradation of performance of the MTJ. In addition, a metal electrode used as a growth matrix of the MTJ is mismatched with a lattice structure of the MTJ, and the MTJ thin film has more defects due to stress, diffusion of the metal electrode elements and other factors, which ultimately leads to the degradation of performance of the magnetic memory cell.

In summary, how to solve the degradation of performance of a device caused by the interface diffusion and interface contact defects in a high temperature process in the related art is an urgent problem to be solved by those skilled in the art.

### SUMMARY

An objective of the disclosure is to provide a magnetic memory cell and a magnetic memory.

The disclosure provides a magnetic memory cell, which sequentially includes a first electrode, a transition combination layer, an MTJ, and a second electrode from bottom to top.

The first electrode and the second electrode are used to connect to an external circuit, and used to control a resistance state of the MTJ.

The transition combination layer includes at least one boron supply layer and at least one boron adsorption buffer layer that are stacked.

Optionally, in the magnetic memory cell, the transition combination layer includes at least of one of following: a plurality of the boron supply layers and a plurality of the boron adsorption buffer layers.

Optionally, in the magnetic memory cell, the plurality of the boron supply layers are alternately stacked with the plurality of the boron adsorption buffer layers.

Optionally, in the magnetic memory cell, the transition combination layer sequentially includes a first boron adsorption buffer layer, the boron supply layer, and a second boron adsorption buffer layer from bottom to top.

Optionally, in the magnetic memory cell, the at least one boron adsorption buffer layer includes at least one of metal molybdenum, chromium, hafnium, zirconium, magnesium, aluminum, zinc, titanium, vanadium and niobium.

Optionally, in the magnetic memory cell, the boron supply layer includes at least one of cobalt boride, iron boride, nickel boride, cobalt iron boron, cobalt iron chromium boron and tantalum boride.

Optionally, in the magnetic memory cell, a range of a thickness of at least one of the at least one boron adsorption buffer layer and the at least one boron supply layer is 0.3 nm to 0.8 nm, and the range includes endpoint values.

Optionally, in the magnetic memory cell, the MTJ further includes a synthetic antiferromagnetic structure layer.

Optionally, in the magnetic memory cell, the MTJ is in contact with the at least one boron supply layer.

A magnetic memory is provided, which includes the magnetic memory cell as described in any one of the above.

### BRIEF DESCRIPTION OF THE DRAWINGS

In order to more clearly illustrate the embodiments of the disclosure or the technical solutions in the related art, the drawings used in the description of the embodiments or the related art will be briefly described below. It is apparent that the drawings described below are only some embodiments of the disclosure. Other drawings may further be obtained by those of ordinary skill in the art according to these drawings without creative efforts.

FIG. 1 is a schematic structural diagram of a specific implementation of a magnetic memory cell provided by the disclosure.

FIG. 2 is a schematic structural diagram of another specific implementation of a magnetic memory cell provided by the disclosure.

FIG. 3 is a schematic structural diagram of still another specific implementation of a magnetic memory cell provided by the disclosure.

FIG. 4 is the experimental result of the degradation of exchange-coupling field (Hex) and coercivity (Hc) after high temperature annealing of the disclosure comparing with those of the prior art.

FIG. 5 is the experimental result of the breakdown voltage of the disclosure comparing with those of the prior art.

### DETAILED DESCRIPTION OF THE EMBODIMENTS

In order to make the solutions of the disclosure understood by those skilled in the art, the disclosure will be described below in detail in combination with the drawings and the specific implementations. It is apparent that the described embodiments are only a part of the embodiments of the disclosure, and not all of them. All other embodiments obtained by those of ordinary skill in the art based on the embodiments of the disclosure without creative efforts are within the scope of the schematic structural diagram of another specific implementation of a magnetic memory cell provided by the disclosure.

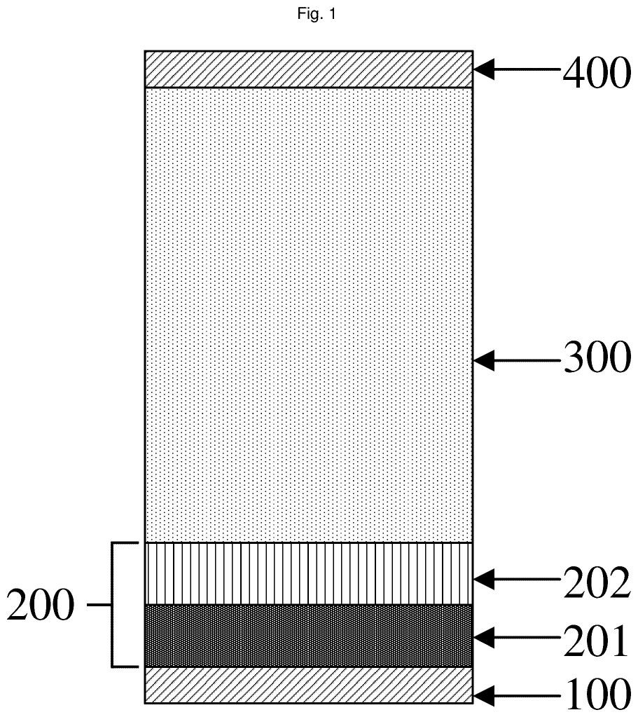

The core of the disclosure is to provide a magnetic memory cell, and a schematic structural diagram of a specific implementation thereof is as shown in FIG. 1, which sequentially includes a first electrode 100, a transition combination layer 200, an MTJ 300, and a second electrode 400 from bottom to top.

The first electrode 100 and the second electrode 400 are used to connect to an external circuit, and used to control a resistance state of the MTJ 300.

The transition combination layer 200 includes at least one boron supply layer 201 and at least one boron adsorption buffer layer 202 that are stacked.

The at least one boron adsorption buffer layer 202 includes at least one of metal molybdenum, chromium, hafnium, zirconium, magnesium, aluminum, zinc, titanium, vanadium and niobium, in other words, the boron adsorption buffer layer 202 is any of the above metal layers, or an alloy layer including any of the above metals, of course, other materials may also be selected according to the actual situation. The above metals have good adsorbability of boron. The boron diffusion and adsorption will happen between the above metals and the boron supply layer 201 at high temperature, and then an alloy with high stability and strong perpendicular magnetic anisotropy is formed, which may slow down the interface diffusion of other film materials in the MTJ. In addition, the alloy with strong perpendicular magnetic anisotropy affects the pinning layer through interlayer magnetic coupling effects and enhances the magnetic stability of the pinning layer, thereby improving the magnetization reversal characteristic of the magnetic memory cell.

Further, the at least one boron supply layer 201 includes at least one of cobalt boride, iron boride, nickel boride, cobalt iron boron, cobalt iron chromium boron and tantalum boride, of course, other materials may also be selected according to the actual situation.

In addition, a thickness of the boron adsorption buffer layer 202 and/or the boron supply layer 201 ranges from 0.3 nm to 0.8 nm, including endpoint values such as any of 0.30 nm, 0.65 nm or 0.8 nm.

The MTJ 300 includes a fixed layer, a barrier layer, and at least one free layer. The fixed layer includes a seed layer, a pinning layer, a reference layer, etc. The seed layer is a single layer of Pt, Pd, Ru, NiCr or NiFeCr film, or a multilayer film stack composed of two or more of CoFeB, TaN, Mg, Pt, Pd, Ru, NiCr and NiFeCr. The pinning layer is a multilayer film stack composed of Co, Pt, Ir, Ru and CoFeB. The reference layer includes at least one of Co, Fe, Ni, CoB, FeB, NiB, CoFe, NiFe, CoNi and CoFeB. The barrier layer includes MgO, or one of MgO doped with elements such as Al, Zn, Hf, etc. Of course, the same MTJ 300 may include a plurality of the free layers or other structures, which will not be listed here.

The MTJ 300 further includes a synthetic antiferromagnetic structure layer. The synthetic antiferromagnetic structure layer is arranged in the fixed layer of the MTJ 300, and the synthetic antiferromagnetic structure layer may effectively reduce the influence of the stray field of the fixed layer on the magnetization reversal of the free layer. The synthetic antiferromagnetic structure layer includes a magnetic multilayer film and a coupling layer, the magnetic multilayer film including at least one of a Co/Pt multilayer film, a Co/Pd multilayer film, and a Co/Ni multilayer film, and the material of the coupling layer is at least one of Ru and Ir.

The boron content of the boron supply layer 201 may change with a matrix material of the boron supply layer 201, for example, when the matrix material of the boron supply layer 201 is CoFeB, the thickness is 0.5 nm, and a ratio of Co to Fe is 1 to 3, the boron content is 20 at. %. In another embodiment, the matrix material of the boron supply layer 201 is CoB with the thickness of 0.3 nm and the boron content of 25 at. %.

The magnetic memory cell provided by the disclosure sequentially includes the first electrode 100, the transition combination layer 200, the MTJ 300, and the second electrode 400 from bottom to top. The first electrode 100 and the second electrode 400 are connected to the external circuit, and control the resistance state of the MTJ 300. The transition combination layer 200 includes the at least one boron supply layer 201 and the at least one boron adsorption buffer layer 202 that are stacked. According to the disclosure, the transition combination layer 200 is provided, so that the problem of stress caused by the mismatch of a metal electrode and a lattice structure of the MTJ 300 is eliminated. Therefore, a perfect motherboard is formed for the growth of the MTJ 300, and the number of defects and the internal stress in the MTJ 300 are reduced. In addition, in a high temperature environment, the boron diffusion and adsorption will happen between the boron supply layer 201 and the boron adsorption buffer layer 202, and then an alloy with high stability and strong perpendicular magnetic anisotropy is formed. The above process consumes internal heat of the MTJ, and effectively slows down the interface diffusion of other film materials in the MTJ 300 in the high temperature environment, improving the high temperature performance (thermal robust) and the breakdown voltage of the MTJ 300. The alloy with strong perpendicular magnetic anisotropy affects the pinning layer through interlayer magnetic coupling effects and enhances the magnetic stability of the pinning layer, and improves the magnetization reversal characteristic of the magnetic memory cell, thereby greatly improving the quality of the finished magnetic memory cell.

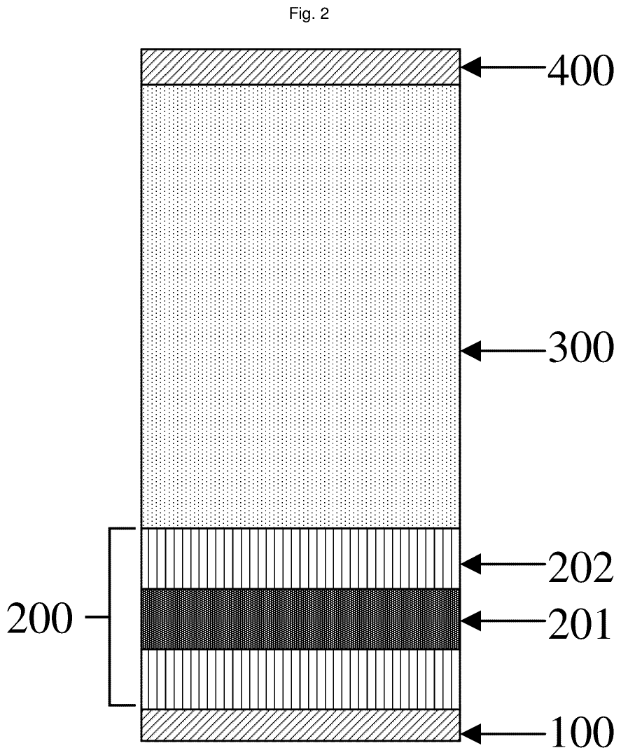

On the basis of a first specific implementation, the composition of the transition combination layer 200 is further limited to obtain a second specific implementation, and a schematic structural diagram thereof is as shown in FIG. 2, which sequentially includes a first electrode 100, a transition combination layer 200, an MTJ 300, and a second electrode 400 from bottom to top.

The first electrode 100 and the second electrode 400 are used to connect to an external circuit, and used to control a resistance state of the MTJ 300.

The transition combination layer 200 includes at least one boron supply layer 201 and at least one boron adsorption buffer layer 202 that are stacked.

The transition combination layer 200 includes at least of one of following: a plurality of the boron supply layers 201 and/or a plurality of the boron adsorption buffer layers 202.

The transition combination layer 200 in the specific implementation is a combination layer composed of three or more single layers, that is, the transition combination layer 200 in the specific implementation may include one boron supply layer 201 and the plurality of the boron adsorption buffer layers 202, or one boron adsorption buffer layer 202 and the plurality of the boron supply layers 201, or the plurality of the boron supply layers 201 and the plurality of the boron adsorption buffer layers 202, which may be adjusted according to the manufacturing temperature of a device in actual production, and increase or decrease the number of layers to adjust the diffusion amount of boron, thereby obtaining a better effect of preventing the interface diffusion of the MTJ 300.

Further, the plurality of the boron supply layers 201 are alternately stacked with the plurality of the boron adsorption buffer layers 202, so that the boron of the transition combination layer 200 made of the same amount of raw materials is more thoroughly diffused, which is more conducive to the formation of an alloys with high stability and strong perpendicular magnetic anisotropy, achieving a better effect of preventing the interface diffusion of the MTJ 300, as well as improving the magnetization reversal characteristic, and upgrading the breakdown voltage.

Further, the transition combination layer sequentially includes a first boron adsorption buffer layer, the boron supply layer 201, and a second boron adsorption buffer layer from bottom to top. As shown in FIG. 2, the two boron adsorption buffer layers 202 isolate the boron supply layer 201 from other structures on both sides to avoid the degradation of the device performance caused by the boron entering other structures of the MTJ in the process of the diffusion of the boron at the high temperature, thereby further improving the quality of the finished magnetic memory cell.

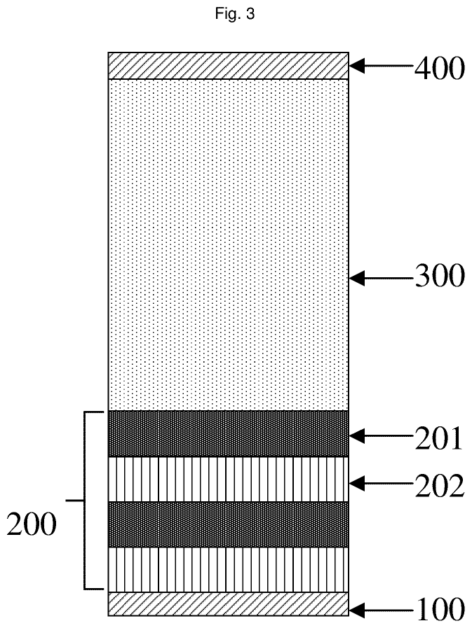

On the basis of the second specific implementation, the position of the boron supply layer 201 is further limited to obtain a third specific implementation, and a schematic structural diagram thereof is as shown in FIG. 3, which sequentially includes a first electrode 100, a transition combination layer 200, an MTJ 300, and a second electrode 400 from bottom to top.

The first electrode 100 and the second electrode 400 are used to connect to an external circuit, and used to control a resistance state of the MTJ 300.

The transition combination layer 200 includes at least one boron supply layer 201 and at least one boron adsorption buffer layer 202 that are stacked.

The transition combination layer 200 includes at least of one of following: a plurality of the boron supply layers 201 and a plurality of the boron adsorption buffer layers 20.

The MTJ 300 is in contact with one of the boron supply layer 201.

In the specific implementation, the MTJ 300 is arranged on the boron supply layer 201, the general boron supply layer 201 may provide a smoother and flatter thin film surface, which improves the interface characteristics of the MTJ 300, and causes better uniformity of the MTJ 300, and the performance across the interface to be consistent.

The disclosure further provides a magnetic memory, which includes the magnetic memory cell as described in any one of the above. The magnetic memory cell provided by the disclosure sequentially includes a first electrode 100, a transition combination layer 200, an MTJ 300, and a second electrode 400 from bottom to top. The first electrode 100 and the second electrode 400 are used to connect to an external circuit, and used to control a resistance state of the MTJ 300. The transition combination layer 200 includes at least one boron supply layer 201 and at least one boron adsorption buffer layer 202 that are stacked. According to the disclosure, the transition combination layer 200 is provided, so that the problem of stress caused by the mismatch of a metal electrode and a lattice structure of the MTJ 300 is eliminated. The boron supply layer and the boron adsorption buffer layer set in a cascade have smoother surfaces, therefore a better motherboard is provided for the subsequent growth of the MTJ 300, and the number of defects and the internal stress in the MTJ 300 are reduced. In addition, in a high temperature environment, boron diffusion and adsorption will happen between the boron supply layer 201 and the boron adsorption buffer layer 202, and then an alloy with high stability and strong perpendicular magnetic anisotropy is formed. The above process consumes internal heat of the MTJ, which effectively slows down the interface diffusion of other film materials in the MTJ 300 in the high temperature environment, and improves the high temperature performance (thermal robust) and the breakdown voltage of the MTJ 300. The alloy with strong perpendicular magnetic anisotropy affects the pinning layer through interlayer magnetic coupling effects and enhances the magnetic stability of the pinning layer, thereby greatly improving the quality of the finished magnetic memory cell.

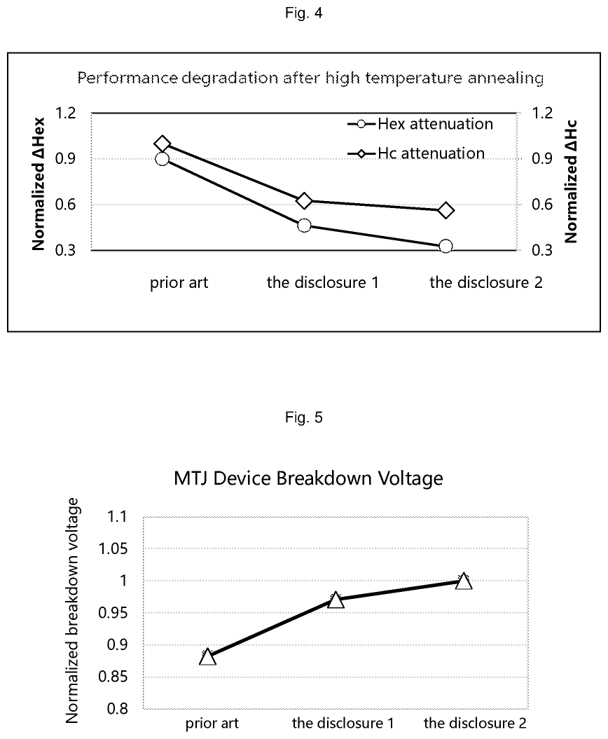

FIG. 4 and FIG. 5 provide respectively a comparison of the experimental results of the exchange-coupling field (Hex) and coercivity (Hc) degradation after high temperature annealing and the breakdown voltage of the disclosure comparing with those of the prior art. In the prior art, after high temperature annealing (e.g., 400° C.), the exchange-coupling field (Hex) and coercivity (Hc) are attenuated due to the diffusion of elements between the membrane layers of the MTJ.

The experiments have shown that, due to set the transition combination layer in the MTJ in the disclose, the attenuation of Hex and He of the MTJ is weakened significantly after high temperature annealing (FIG. 4), indicating that the high temperature performance and the magnetization reversal characteristic of the MTJ are improved. In addition, the breakdown voltage of the MTJ device is significantly increased after the transition combination layer is set in the MTJ (FIG. 5), indicating that the breakdown characteristic of the device is improved.

The various embodiments in the present specification are described in a progressive manner, and each embodiment focuses on differences from other embodiments, and the same or similar parts between the various embodiments may be referred to each other. For the apparatus disclosed in the embodiment, since it corresponds to the method disclosed in the embodiment, the description is relatively simple, and the relevant parts can be referred to the method part.

It is to be noted that relational terms “first”, “second” and the like herein are adopted only to distinguish one entity or operation from another entity or operation and not always to require or imply existence of any such practical relationship or sequence between the entities or operations. Furthermore, terms “include” and “contain” or any other variant thereof is intended to cover nonexclusive inclusions herein, so that a process, method, object or device including a series of elements not only includes those elements but also includes other elements which are not clearly listed or further includes elements intrinsic to the process, the method, the object or the device. Under the condition of no more limitations, an element defined by the statement “including a/an . . . ” does not exclude existence of the same other elements in a process, method, object or device including the element.

The magnetic memory cell and the magnetic memory provided by the disclosure are described above in detail. The principles and implementations of the disclosure are described herein using specific examples, the foregoing description of the embodiments are only used to help the understanding of the method and core concept of the disclosure. It is to be noted that a number of variations and modifications may be made by those of ordinary skill in the art without departing from the conception of the disclosure, and all fall within the scope of protection of the disclosure.

1. A magnetic memory cell, sequentially comprising a first electrode, a transition combination layer, a Magnetic Tunnel Junction (MTJ), and a second electrode from bottom to top;
the first electrode and the second electrode are used to connect to an external circuit, and used to control a resistance state of the MTJ; and
the transition combination layer comprises at least one boron supply layer and at least one boron adsorption buffer layer that are stacked.

2. The magnetic memory cell according to claim 1, wherein the transition combination layer comprises at least of one of the following: a plurality of the boron supply layers and a plurality of the boron adsorption buffer layers.

3. The magnetic memory cell according to claim 2, wherein the plurality of the boron supply layers are alternately stacked with the plurality of the boron adsorption buffer layers.

4. The magnetic memory cell according to claim 1, wherein the transition combination layer sequentially comprises a first boron adsorption buffer layer, the boron supply layer, and a second boron adsorption buffer layer from bottom to top.

5. The magnetic memory cell according to claim 1, wherein the at least one boron adsorption buffer layer comprises at least one of metal molybdenum, chromium, hafnium, zirconium, magnesium, aluminum, zinc, titanium, vanadium and niobium.

6. The magnetic memory cell according to claim 1, wherein the at least one boron supply layer comprises at least one of cobalt boride, iron boride, nickel boride, cobalt iron boron, cobalt iron chromium boron and tantalum boride.

7. The magnetic memory cell according to claim 1, wherein a range of a thickness of at least one of the at least one boron adsorption buffer layer and the at least one boron supply layer is 0.3 nm to 0.8 nm, and the range comprises endpoint values.

8. The magnetic memory cell according to claim 1, wherein the MTJ further comprises a synthetic antiferromagnetic structure layer.

9. The magnetic memory cell according to claim 1, wherein the MTJ is in contact with the at least one boron supply layer.

10. A magnetic memory, comprising a magnetic memory cell, wherein the magnetic memory cell sequentially comprises a first electrode, a transition combination layer, a Magnetic Tunnel Junction (MTJ), and a second electrode from bottom to top;
the first electrode and the second electrode are used to connect to an external circuit, and used to control a resistance state of the MTJ; and
the transition combination layer comprises at least one boron supply layer and at least one boron adsorption buffer layer that are stacked.

11. The magnetic memory according to claim 10, wherein the transition combination layer comprises at least of one of the following: a plurality of the boron supply layers and a plurality of the boron adsorption buffer layers.

12. The magnetic memory according to claim 11, wherein the plurality of the boron supply layers are alternately stacked with the plurality of the boron adsorption buffer layers.

13. The magnetic memory according to claim 10, wherein the transition combination layer sequentially comprises a first boron adsorption buffer layer, the boron supply layer, and a second boron adsorption buffer layer from bottom to top.

14. The magnetic memory according to claim 10, wherein the at least one boron adsorption buffer layer comprises at least one of metal molybdenum, chromium, hafnium, zirconium, magnesium, aluminum, zinc, titanium, vanadium and niobium.

15. The magnetic memory according to claim 10, wherein the at least one boron supply layer comprises at least one of cobalt boride, iron boride, nickel boride, cobalt iron boron, cobalt iron chromium boron and tantalum boride.

16. The magnetic memory according to claim 10, wherein a range of a thickness of at least one of the at least one boron adsorption buffer layer and the at least one boron supply layer is 0.3 nm to 0.8 nm, and the range comprises endpoint values.

17. The magnetic memory according to claim 10, wherein the MTJ further comprises a synthetic antiferromagnetic structure layer.

18. The magnetic memory cell according to claim 1, wherein the at least one boron supply layer is CoFeB, a thickness of the boron supply layer is 0.5 nm, and a ratio of Co to Fe is 1 to 3, boron content is 20 at. %.

19. The magnetic memory cell according to claim 1, wherein the at least one boron supply layer is CoB, a thickness of the boron supply layer is 0.3 nm, and boron content is 20 at. %.

20. The magnetic memory cell according to claim 1, wherein the MTJ comprises a fixed layer, a barrier layer, and at least one free layer, the fixed layer includes a seed layer, a reference layer and a pinning layer; the seed layer is a Pt, Pd, Ru, NiCr or NiFeCr single layer film, or a multilayer film stack composed of two or more of CoFeB, TaN, Mg, Pt, Pd, Ru, NiCr and NiFeCr; the reference layer comprises at least one of Co, Fe, Ni, CoB, FeB, NiB, CoFe, NiFe, CoNi and CoFeB; and the barrier layer comprises MgO, or one of MgO doped with Al, Zn and Hf.
